(19) United States
(12) Patent Application Publication
(10) Pub. No.: US 2017/0301851 A1
(43) Pub. Date: Oct. 19, 2017

(54) THERMOELECTRIC DEVICE

(71) Applicant: Mahle International GmbH, Stuttgart (DE)

(72) Inventor: Hans-Heinrich Angermann, Stuttgart (DE)

(73) Assignee: Mahle International GmbH, Stuttgart (DE)

(21) Appl. No.: 15/515,920

(22) PCT Filed: Sep. 23, 2015
(86) PCT No.: PCT/EP2015/071905

§ 371 Date: Mar. 30, 2017

(30) Foreign Application Priority Data
Sep. 30, 2014 (DE) 10 2014 219 855.0

(51) Int. Cl. H01L 35/32; H01L 35/34

(52) U.S. Cl. CPC H01L 35/32; H01L 35/34

(57) ABSTRACT

A thermoelectric device may include at least two thermoelectric elements manufactured from a thermoelectrically active material. The thermoelectric device may also include at least one conductor path element electrically connecting the at least two thermoelectric elements. The thermoelectric device may further include at least one adapter layer made from a metal and disposed on each of the at least two thermoelectric elements and sandwiched between the respective thermoelectric element and the at least one conductor path element.

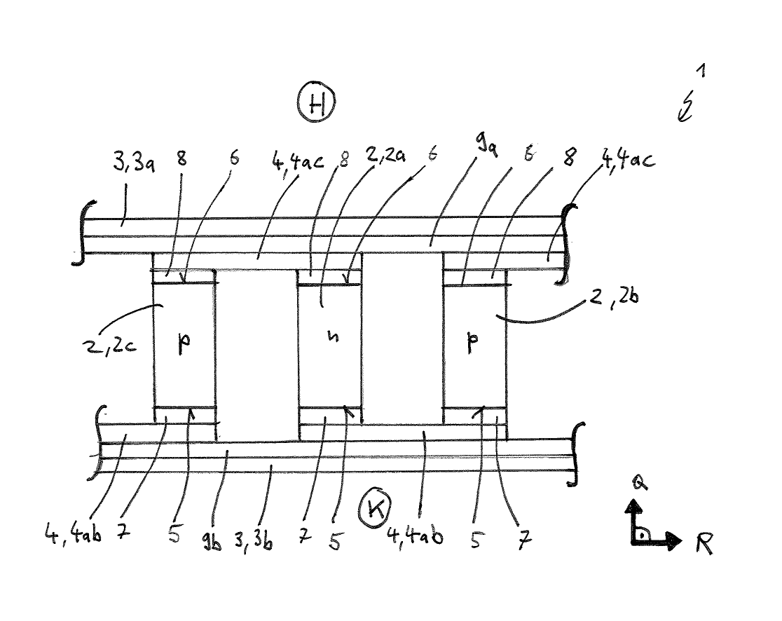

### CROSS-REFERENCE TO RELATED APPLICATIONS

This application claims priority to International Patent Application No. PCT/EP2015/071905, filed on Sep. 23, 2015, and German Patent Application No. DE 10 2014 219 855.0, filed on Sep. 30, 2014, the contents of both of which are incorporated by reference in their entirety.

### TECHNICAL FIELD

The invention relates to a thermoelectric device and a thermoelectric generator having such a thermoelectric device. The invention further relates to a motor vehicle with such a thermoelectric generator as well as a method for manufacturing a thermoelectric device.

The invention relates to a thermoelectric device, in particular a thermoelectric generator or heat pump, and a motor vehicle with such a thermoelectric device.

### BACKGROUND

The term “thermoelectricity” is understood to mean the mutual influence of temperature and electricity and their conversion into each other. Thermoelectric materials make use of this influence to generate electrical energy from waste heat as thermoelectric generators, but they are also used in the form of “heat pumps” when heat is to be transferred from a temperature reservoir at a lower temperature to one at a higher temperature using electrical energy.

In motor vehicles with an internal combustion engine, thermoelectric generators can convert part of the waste heat in the exhaust gas generated during the combustion process into electrical energy and feed it into the onboard electrical system of the motor vehicle. This waste heat which has been converted into electrical energy may thus be used to lower the energy consumption of the motor vehicle to a functionally necessary minimum, thereby avoiding unnecessary emission of exhaust gases such as CO₂. Thus, the variety of possible application areas for thermoelectric devices in automobile construction is very diverse. In every possible application scenario, it is critically important to achieve a high level of efficiency when converting heat into electrical energy or vice versa as effectively as possible. Their use in motor vehicles also entails the additional requirement of manufacturing thermoelectric devices in compact form.

Thermoelectric devices fitted in vehicles are therefore often manufactured in a panel or layer construction, wherein the thermoelectrically active elements are arranged inside a thermally conductive housing. This enables the housing to be connected thermally to a low temperature reservoir on one side, the “cold side”, and on the other side to a to a temperature reservoir at a higher temperature—the “hot side”, so that the thermoelectric elements generate a thermoelectric voltage due to the temperature gradient between the two sides, and this voltage can be conducted via suitable electrical connections to the outside, where it can be used. The greater the temperature difference between the hot and cold sides, the larger the thermoelectric voltage generated by the device.

A thermoelectric device typically comprises a plurality of thermoelectric elements made from thermoelectrically active materials, which are connected to each other by suitable electrically conductor paths in the manner of a serial electrical circuit. In this context, such an electrically conductor path particularly connects two adjacent thermoelectric elements.

With regard to such conductor paths, difficulties are typically associated with affixing them firmly to the thermoelectric elements without an undesirably high electrical resistance being created in the transition area between the thermoelectric element and conductor path, which resistance causes the electrical energy generated by the thermoelectric element to dissipate before it reaches the outside. There is also the risk that thermoelectrically active material in the area of the hot side of the thermoelectric device may diffuse into the material of the conductor path and the bonding material, or vice versa, with the result that the Seebeck coefficient of the thermoelectric element may be lowered quite considerably.

Against this background, DE 10 2012 208 295 A1 describes a thermoelectric module with a thermoelectric element that is mounted on a housing element. A joining seam area formed by compressing a joining material is provided between the two elements. A diffusion barrier may be provided on the thermoelectric element to prevent the bonding material from penetrating the thermoelectrically active material of the thermoelectric element, which is not desirable.

Document WO2011/159804 A2 discloses a thermoelectric device with thermoelectrically active elements made from a skutterudite. The device comprises a layer which is sandwiched between the thermoelectrically active element and a metal layer provided to ensure electrical contact and functions as a diffusion barrier. In one variant, the metal layer may also be provided between the diffusion barrier and thermoelectric element.

### SUMMARY

It is an object of the present invention to provide an improved embodiment of a thermoelectric device in which the problems described above are eliminated.

This object is solved with the subject matter of the independent claims. Preferred embodiments are the subject of the respective dependent claims.

Accordingly, the basic idea of the invention is to metallise thermoelectrically active elements of a thermoelectric device—in the following, these will be referred to more simply as “thermoelectric elements”—in a particular way, that is so say equipped with at least one adapter layer made of a metal, which is provided on one surface of the respective thermoelectric element. Thus, an electrically conductive track can be applied to the adapter layer, which functions in the manner of an electrical series connection for electrically connecting two adjacent thermoelectric elements. Providing such a metallic adapter layer favours a reliable mechanical bond between the electrically conductive tracks—hereinafter referred to as conductor path elements—on the thermoelectric element. Moreover, such a metal layer also has the properties an advantageous diffusion barrier. Finally, with the aid of the adapter layer described here, it is possible to obtain a low electrical resistance in the transition area between the thermoelectric element and the conductor path element, which is advantageous for the thermoelectric properties of the entire apparatus.

Particularly low electrical resistance in said transition area may be achieved by selecting a material with the lowest possible electrical resistance for the metal of the adapter layer. Experimental tests have shown that the thermoelectric properties of the thermoelectric device are only limited insignificantly, or not at all, when the metal of the adapter layer has a resistivity of less than 0.9 Ωcm, preferably less than 0.2 Ωcm, most preferably less than 0.03 Ωcm.

Such low electrical resistivities can be achieved if metals with little or no alloy content are used. Particularly good results for the purposes of the required high electrical conductivity are achieved if it is ensured by suitable choice of material that the metal of the adapter layer has an alloy content of less than 10% by weight, preferably less than 5% by weight, most preferably less than 2% by weight.

Particularly suitable candidate materials for use as the metal adapter layer include silver and copper, since these have an electrical resistance of only 0.016 Ωcm or 0.017 Ωcm. The use of silver is typically associated with significantly higher procurement costs than copper. On the other hand, silver has proven to be more resistant to oxidation than copper. Therefore conductor path elements can be applied to silver without using a flux material.

It is particularly expedient if the adapter layer consists of a silver layer or a copper layer, that is to say, in such a scenario—apart from impurities in form of a negligible number of foreign atoms—no substances other than silver or copper are contained in the adapter layer.

In order to provide an adapter layer with good bonding properties, it is recommended to use a spraying method to apply the adapter layer to each of the thermoelectric elements concerned. It is advantageous if the thermoelectric elements have a roughness, into which the spray coating can “key” during. Such roughness may be created by the usual methods such as sand blasting, grinding, eroding etc. An essential characteristic of such a sprayed adapter layer is the roughness achieved with the spraying process. A bonding material by which the electrical conductor path is bonded to the thermoelectric element, may also “key” on an adapter layer with such roughness with good mechanical results.

Significant cost advantages can be realised in the manufacture of the adapter layer if the new layer is constructed from at least two layers, initially from a sprayed layer of an inexpensive material such as copper, nickel, iron or titanium, thereby ensuring the roughness of the adapter layer, and at least a second, thin layer of silver or copper. This second layer is not applied by spraying, but by a PVD process or by electroplating, particularly by brush electroplating. A layer thickness of the second, thin film should preferably be less than 10 μm. A conductor path element may then be applied to a second thin—and thus low-cost—layer comprising silver without using a flux.

Antimony (Sb) has proven to be a particularly suitable component of material systems for the thermoelectrically active material of the thermoelectric elements, and is characterised by particularly pronounced thermoelectric activity.

The invention further relates to a thermoelectric generator, particularly for a motor vehicle, with at least one thermoelectric device having one or more of the aforementioned characteristics.

The invention further relates to a motor vehicle with at least one power supply unit, particularly a rechargeable battery and the thermoelectric generator described above.

Finally, the invention relates to a method for manufacturing a thermoelectric device, in particular a thermoelectric device having one or more of the features discussed in the preceding text. The method includes a first step a), according to which at least two thermoelectric elements of a thermoelectrically active material are provided, in particular adjacent but at a distance from one another. The method presented here therefore explicitly comprises devices having more than two thermoelectric elements.

In a second step b), an adapter made of a metal layer is applied to each thermoelectric element. Typically, such an adapter layer may be applied to two different, preferably two opposite sides of each thermoelectric element, so that the two sides may be used for an electrical connection with adjacent thermoelectric elements. This can be accomplished by using a joining process familiar to the person skilled in the art, such as a soldering process or a sintering process, for example, in the latter case particularly by silver sintering or spark plasma sintering.

For this purpose, in a further step c) of the method, each conductor path element is applied to the adapter layers in such a way that it creates an electrical connection between adjacently arranged thermoelectric elements.

For the standard practice case in which a plurality of thermoelectric elements are arranged adjacent to each other, a given thermoelectric element may be connected to a first thermoelectric element, which is adjacent thereto in the direction of extension, via a first conductor bridge, which is applied to a first adapter layer. The same thermoelectric element is then connected in similar manner to a second thermoelectric element, which is adjacent thereto in the direction counter to the extension, via a second conductor bridge, which is applied to a second adapter layer opposite the first. This enables a space-saving, “chain-like” arrangement of theoretically any number of thermoelectric elements.

Cost advantages in the manufacture of the thermoelectric device, without also sacrificing the adhesive strength of the adapter layer on the thermoelectric elements and/or the adhesive strength of the joining material on the adapter layer, can be obtained if the adapter layer is applied according to step b) by a spraying method, particularly by arc wire spraying or cold gas spraying. In the second method, the metallic coating powder only has to be heated to a temperature of a few 100° C., so that the mechanical stresses induced in the cooling process that follows the heating process—due to the temperature difference between the coating powder and the surface to be coated—are at all events too minor to be significant.

Particularly good adhesion properties of the surfaces of the thermoelectric elements to be coated are obtained if the process is supplemented with step a1) subsequent to step a):

a1) roughening the surface of the thermoelectric material by means of a blasting process, particularly a sand blasting process, or by grinding on a grinding medium that is adjusted to the desired target roughness.

Further important features and advantages of the invention will be apparent from the dependent claims, from the drawing and from the associated description of the figure with reference to the drawing.

Of course, the features described above and those yet to be explained in the following text can be used not only in the specific combination indicated but also in other combinations or alone without departing from the scope of the present invention.

Preferred embodiments of the invention are illustrated in the drawing and will be explained in greater detail in the following description, wherein like reference numerals refer to identical or similar or functionally equivalent components.

### BRIEF DESCRIPTION OF THE DRAWINGS

The FIGURE shows a thermoelectric device.

### DETAILED DESCRIPTION

The single figure shows a thermoelectric device 1, for a thermoelectric generator for example. This has a plurality of thermoelectric elements 2 arranged adjacent to and at a distance to each other along a direction of extension R. In the example scenario of the figure, for the sake of clarity only three such elements 2a, 2b, 2c are shown, adjacent to and at a distance from each other, each of which has in alternating pattern the thermoelectric p-material and n-material familiar to the person skilled in the art, containing antimony (Sb) for example.

Thermoelectric device 1 may be equipped with a housing 3 made from a metal. In the figure, housing 3 is shown only partially and schematically in the form of two opposing housing walls 3a, 3b, which can be thermally coupled to the hot side H and the cold side K of the generator. In the example of the figure, an electrically insulating layer 9a, 9b is provided between the thermoelectric elements 2 and each of the two opposing housing walls 3a, 3b to electrically insulate the thermoelectric elements 2 from metallic housing 3. The electrically insulating layers 9a, 9b may be made of a ceramic, for example, or some other suitable, electrically insulating material with high thermal conductivity.

Each thermoelectric element 2 has a first side 5 extending along a transverse direction Q extending transversely to direction of extension R and a second side 6 positioned opposite the first side. Each of the thermoelectric elements 2 is also connected to an adjacent thermoelectric element 2 via at least one conductor path element 4. Conductor path elements 4 may be manufactured from a metal having the lowest possible electrical resistivity. Metals that might be considered for such particularly include copper, nickel, or iron.

In the case that a given thermoelectric element 2—in the figure, this is the element 2a which is arranged in the middle relative to direction of extension R—has neighbours 2b and 2c both in and counter to the direction of extension R, a first conductor path element 4ab, disposed on the first side 5 of thermoelectric elements 2 serves to create an electrical connection between the given thermoelectric element 2a with its neighbour 2b in direction of extension R. A further, second conductor path element 4ac disposed on the second side 6 of thermoelectric element 2 serves in similar manner to create an electrical connection between element 2a and its neighbour 2c. Thus, individual thermoelectric elements 2a, 2b, 2c are connected to each other electrically in the manner of a series circuit with the aid of conductor path elements 4ab, 4ac. As shown in the figure, first conductor path element 4ab connects the first two sides 5 of the two thermoelectric elements 2a, 2b, second conductor path element 4ac connects the second two sides 6 of the two thermoelectric elements 2a, 2c.

One adapter layer 7, 8 made of metal is provided on both the first side 5 and on the second side 6 of thermoelectric elements 2a, 2b, 2c, sandwiched between the respective thermoelectric element 2a 2b, 2c and the respective conductor path element 4ab, 4ac. In the example of the figure the metal of the adapter layer is or comprises silver or copper. The former has an electric resistivity of 0.016 Ωcm, the latter 0.017 Ωcm. But silver has proven to be particularly resistant to oxidation. Furthermore, electrical conductor elements 4, 4ab, 4ac may be applied to silver advantageously without using a flux, the muster. It is particularly expedient if the adapter layer consists of a layer of pure silver or a layer of pure copper. Then—apart from impurities in form of a negligible number of foreign atoms—no substances other than silver or copper are contained in the adapter layer. However, in variants of the example other metals which have an electrical resistivity of less than 0.9 Ωcm, preferably less than 0.2 Ωcm, most preferably less than 0.03 Ωcm, are possible. Such resistance values may be achieved for example if metals with very low or even no alloy content are used. Conceivable is an alloy content of less than about 10% by weight, preferably less than 5% by weight, most preferably less than 2% by weight.

In order to apply adapter layers 7, 8 to the thermoelectric elements 2, 2a, 2b, 2c with good adhesion properties, it is recommended to use a spray process, for example arc wire spraying or cold spraying. In cold spraying, the metallic coating powder only has to be heated to a temperature of a few 100° C., so that the mechanical stresses induced by the temperature difference between the coating powder and the surface to be coated in the cooling process that follows the heating process are insignificant.

The respective first and second sides 5, 6 of the thermoelectric elements 2, 2a, 2b, 2c may be roughened by means of a blasting method, for example a sand blasting method, or a grinding method, before the adapter layers 7, 8 are applied.

A joining material applied in a subsequent step may key well mechanically in the sprayed and roughened adapter layers 7, 8. Of course, not all of the adapter layers 7, 8 must consist of silver, but the desired roughness of the adapter layer 7, 8 overall is also achieved with a first sprayed layer of a material that is less expensive than silver, such as nickel, copper, iron or titanium with a low electrical resistivity, to which a second thin layer is then applied, made of silver or even of copper, by means of PVD, electroplating or brush plating, for example.

1. A thermoelectric device, comprising:
at least two thermoelectric elements manufactured from a thermoelectrically active material;
at least one conductor path element electrically connecting the at least two thermoelectric elements; and
at least one adapter layer made from a metal and disposed on each of the at least two thermoelectric elements and sandwiched between the respective thermoelectric element and the at least one conductor path element.

2. The thermoelectric device according to claim 1, wherein the metal of the at least one adapter layer has an electrical resistivity that is less than 0.9 Ωcm.

3. The thermoelectric device according to claim 1, wherein the metal of the adaptor layer has an alloy content of less than 10% by weight.

4. The thermoelectric device according to claim 1, wherein the metal of the adapter layer includes one of silver and copper.

5. The thermoelectric device according to claim 1, wherein the adapter layer consists of one of a silver layer and a copper layer.

6. The thermoelectric device according to claim 1, wherein the adapter layer includes at least two layers, of which at least one is applied to the respective thermoelectric element by thermal spraying.

7. The thermoelectric device according to claim 6, wherein one of the at least two layers includes one of copper, nickel, iron, and titanium, and is applied via a thermal spray process.

8. The thermoelectric device according to claim 6, wherein one of the at least two layers:
includes one of copper and silver;
has a layer thickness of less than 10 μm; and
is applied to to another of the at least two layers via one of physical vapour deposition (PVD) and an electroplating process.

9. The thermoelectric device according to claim 1, wherein the at least one adapter layer is sprayed onto the at least two thermoelectric elements.

10. The thermoelectric device according to claim 1, wherein the thermoelectrically active material includes antimony.

11. A thermoelectric generator comprising at least one thermoelectric device having:
at least two thermoelectric elements manufactured from a thermoelectrically active material;
at least one conductor path element electrically connecting the at least two thermoelectric elements; and
at least one adapter layer made from a metal and disposed on each of the at least two thermoelectric elements and sandwiched between the respective thermoelectric element and the at least one conductor path element.

12. A motor vehicle comprising at least one energy supply unit and a thermoelectric generator including at least one thermoelectric device having:
at least two thermoelectric elements manufactured from a thermoelectrically active material;
at least one conductor path element electrically connecting the at least two thermoelectric elements; and
at least one adapter layer made from a metal and disposed on each of the at least two thermoelectric elements and sandwiched between the respective thermoelectric element and the at least one conductor path element.

13. A method for producing a thermoelectric device, comprising:
providing at least two thermoelectric elements from a thermoelectrically active material;
applying an adapter layer made from a metal to each of the at least two thermoelectric elements; and
applying an electrical conductor path to the adapter layers such that the at least two thermoelectric elements are electrically connected to each other electrically.

14. The method according to claim 13, wherein applying the adapter layer is carried out by spraying process.

15. The method according to claim 13, further comprising after providing the at least two thermoelectric elements:
roughening a surface of the thermoelectrically active material by one of a blasting process, a grinding process, and an eroding process.

16. The method according to claim 15, wherein the blasting process is a sand blasting process.

17. The method according to claim 14, wherein the spraying process includes one of arc wire spraying and cold gas spraying.

18. The motor vehicle of claim 12, wherein the at least one energy supply unit is a rechargeable battery.

19. The thermoelectric device according to claim 2, wherein the electrical resistivity is less than 0.03 Ωcm.

20. The thermoelectric device according to claim 3, wherein the alloy content is less than 2% by weight.
